(19) United States
(12) Patent Application Publication
(10) Pub. No.: US 2005/0110168 A1
(43) Pub. Date: May 26, 2005

(54) Low coefficient of thermal expansion (CTE) semiconductor packaging materials

(75) Inventor: Shih-Fang Chuang, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/717,731

(22) Filed: Nov. 20, 2003

(51) Int. Cl. H01L 23/29; H01L 21/50

(52) U.S. Cl. 257/788; 257/787; 438/126; 438/127

(57) ABSTRACT

A low-CTE packaging material for assembling a semiconductor die into a package and a method for assembling a semiconductor die into a package, in which the packaging material comprises a negative-CTE material. The low-CTE packaging material in accordance with the embodiments of the invention may be a die attach material, a lid attach material, or an encapsulant, such as a mold compound or glob-top material. Preferably, the negative-CTE material is a tungstate compound, such as zirconium tungstate, halfnium tungstate or a solution of zirconium and halfnium tungstate.

### BACKGROUND OF THE INVENTION

Integrated circuits are fabricated on the surface of a semiconductor wafer in layers and later singulated into individual dies. Since the material of a semiconductor wafer—commonly silicon—tends to be relatively fragile and brittle, dies are often assembled into a protective housing, or package, before they are interconnected with a printed circuit board (PCB). These assembled dies and their surrounding packages may be referred to as “packaged semiconductor devices.”

A concern in packaging technology is the respective coefficients of thermal expansion (CTE) of adjacent materials within a package. A CTE is a physical value that denotes the tendency of a material to expand in relation to temperature increases. As shown in Table 1 below, a silicon die may have a CTE of about 3 ppm/C, while surrounding packaging materials may have significantly higher CTE values. Exemplary values for an encapsulant are represented for encapsulants below their respective glass transition temperatures, T_{g}.

TABLE 1
Exemplary Packaging Material CTE Values

| | CTE (ppm/C) |
|---|---|
| Silicon (Si) | 2.5-3.0 |
| Die Attach (Epoxy) | 20-70 |
| Encapsulant | 7-60 |
| (Epoxy)* | |
| Lid Attach | 20-70 |
| LGA Lid | 6.5-20 |

*Below T_{g}

When a relatively expansive—or high-CTE—material is coupled to a less expansive—or low-CTE—material, high stresses may result at the interface of the two materials. The more expansive material applies a tensile force along the surface of the less expansive material, trying to stretch the low-CTE surface. This tensile force can crack, rip or otherwise damage sensitive features or components on or near the surface.

### BRIEF SUMMARY OF THE INVENTION

Disclosed is a low-CTE packaging material for assembling a semiconductor die into a package and a method for assembling a semiconductor die into a package, in which the packaging material comprises a negative-CTE material. A low-CTE packaging material in accordance with the embodiments of the invention may be a die attach material, a lid attach material, or an encapsulant, such as a mold compound or glob-top material. Preferably, the negative-CTE material is a tungstate compound, such as zirconium tungstate, halfnium tungstate or a solution of zirconium and halfnium tungstate.

### BRIEF DESCRIPTION OF THE DRAWINGS

For a detailed description of the preferred embodiments of the invention, reference will now be made to the accompanying drawings in which:

FIG. 1A is a simplified molecular structure of a negative-CTE material prior to thermal excitement;

FIG. 1B shows the simplified molecular structure of FIG. 1A after a temperature increase;

FIG. 2A is a graph of relative material expansion as a function of temperature for the negative-CTE material zirconium tungstate;

FIG. 2B is a graph of relative material expansion as a function of temperature for the negative-CTE material halfnium tungstate;

FIG. 2C is a graph of relative material expansion as a function of temperature for the negative-CTE solution of zirconium and halfnium tungstate;

FIG. 3 is a cross-sectional view of a packaged semiconductor device in a ball grid array (BGA) package; and

FIG. 4 is a cross-sectional view of a packaged semiconductor device in a land grid array (LGA) package.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct electrical connection. Thus, if a first device couples to a second device, that connection may be through a direct electrical connection, or through an indirect electrical connection via other devices and connections.

The term “integrated circuit” refers to a set of electronic components and their interconnections (internal electrical circuit elements, collectively) that are patterned on the surface of a microchip. The term “die” (“dies” for plural) refers generically to an integrated circuit, in various stages of completion, including the underlying semiconductor substrate and all circuitry patterned thereon. The term “wafer” refers to a generally round, single-crystal semiconductor substrate upon which integrated circuits are fabricated in the form of dies. The term “interconnect” refers to a physical connection providing possible electrical communication between the connected items. The term “packaged semiconductor device” refers to a die mounted within a package, as well as all package constituent components. The term “semiconductor package” refers generically to the components for encapsulating and interconnecting a die to a printed circuit board, and is used herein to include an LGA substrate and lid. To the extent that any term is not specially defined in this specification, the intent is that the term is to be given its plain and ordinary meaning.

### DETAILED DESCRIPTION OF THE PREFERRED EMBODIMENTS

Zirconium tungstate (ZrW₂O₈) is a relatively new material having a negative CTE. That is, zirconium tungstate tends to shrink, rather than expand, when heated. If mixed with a typical positive-CTE material to form a composite material, a negative-CTE material such as zirconium tungstate may be able to counteract expansion of the positive-CTE material to form a composite material with little or no thermal expansion. Further, by varying the amount of negative-CTE material introduced into a mixture with the positive-CTE material, the CTE of the composite may be designed to approach a specific value, such as that of a silicon die (e.g., about 3 ppm/C) or another adjacent material.

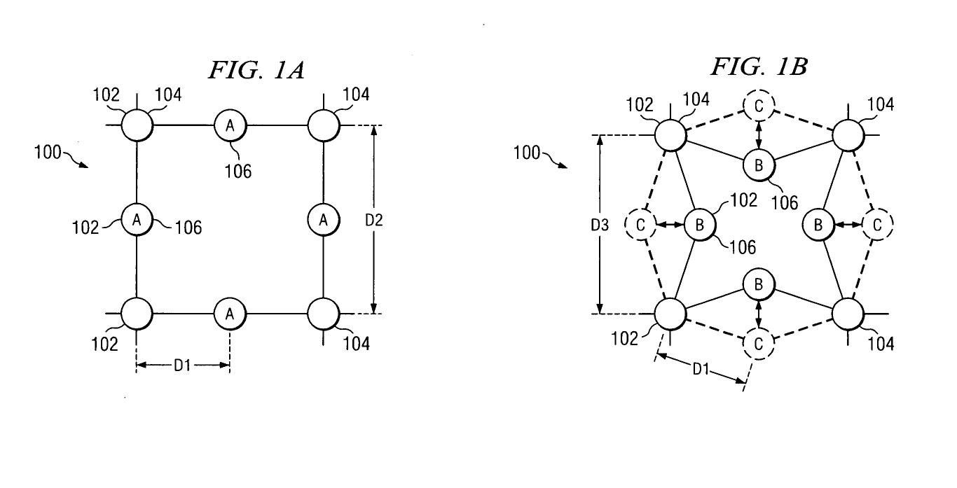

Referring now to FIG. 1A, a simplified molecular lattice structure 100 is shown of a negative-CTE material prior to thermal excitement. In the configuration shown, each atom 102 is at a distance D1 from each adjacent atom on the lattice 100. Each corner atom 104 has a distance D2 from adjacent corner atoms on the lattice 100. Interstitial atoms 106, or atoms 102 between corner atoms 104, may be at positions A, linearly arranged with the adjacent corner atoms. When subjected to a temperature increase, the lattice 100 contracts, as shown in FIG. 1B. Interstitial atoms 106 may vibrate between positions B and C. The distance D1 between each atom 102 is governed by a bond and has to remain largely constant. Consequently, when the interior atoms 106 progress from their initial positions A to oscillating between positions B and C, the distance between each corner atom 104 is shortened into a reduced distance D3, which is less than D2. Accordingly, the entire lattice structure 100 reduces in size.

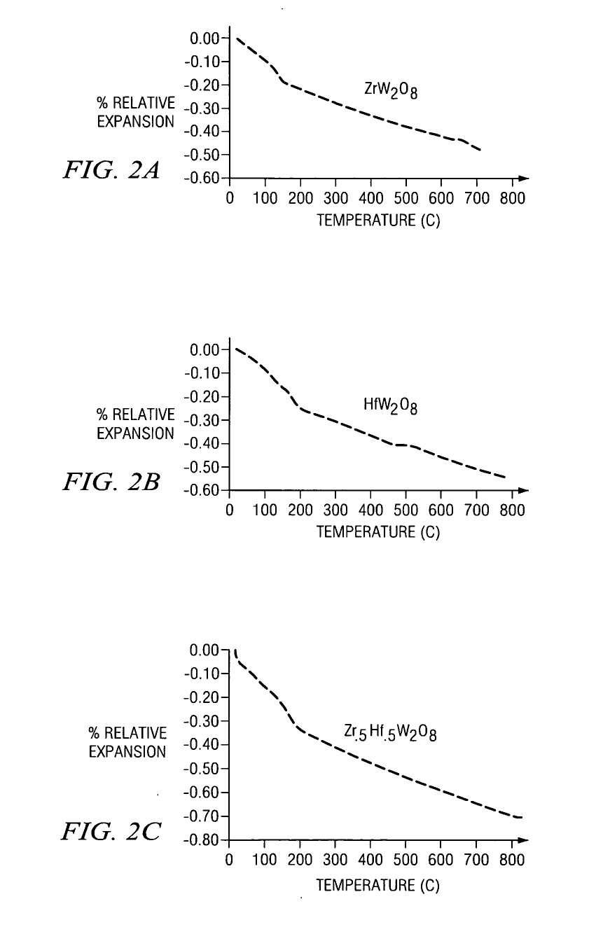

FIGS. 2A-2C show graphs of relative thermal expansion as a function of temperature for the negative-CTE materials zirconium tungstate (ZrW₂O₈), halfnium tungstate (HfW₂O₈), and a solid solution of zirconium and halfnium tungstate (Z_{0.5}Hf_{0.5}W₂O₈), respectively. All three materials have demonstrated negative expansion characteristics over temperature ranges from 25C (i.e., room temperature) to at least 800C. Zirconium tungstate has a nearly uniform negative thermal expansion from near absolute zero to over 800C. This new compound of zirconium, tungstate and oxygen contracts uniformly along all dimensions when heated, even to extreme temperature ranges. This negative expansion is due to the vibration of the oxygen atoms, which bind the atoms of zirconium and tungsten together. As temperatures increase, the oxygen atoms oscillate more dramatically, pulling the other atoms ever closer together. If combined with a higher-CTE material, a negative-CTE material, such as zirconium tungstate, may produce a composite material with a lower overall CTE.

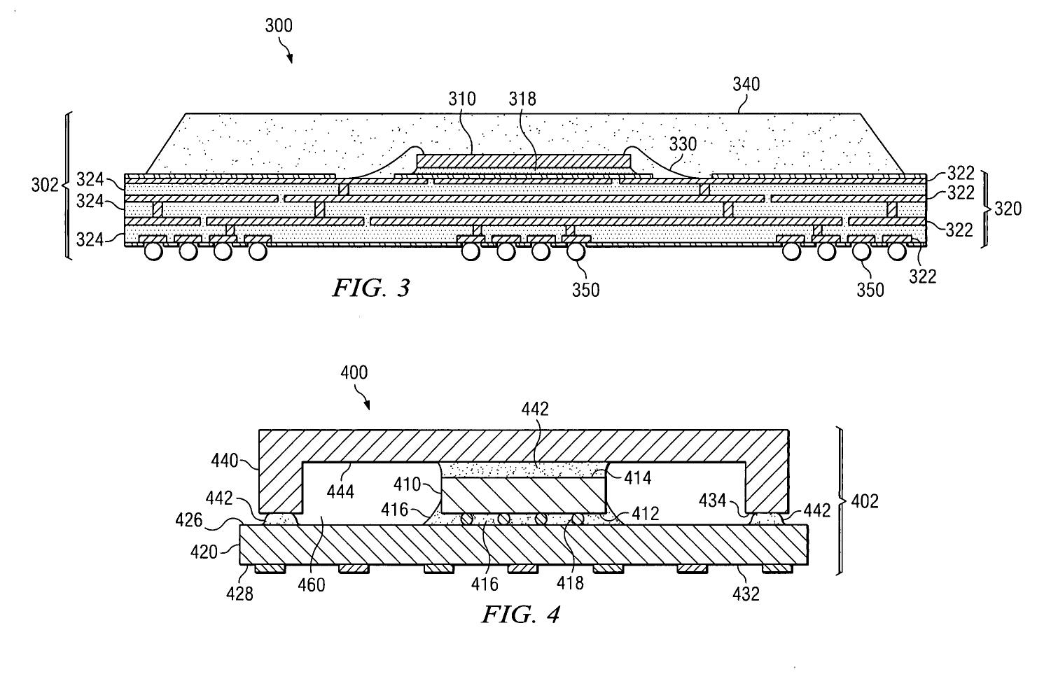

Referring now to FIG. 3, a cross-sectional view is shown of a low-CTE packaged semiconductor device 300 in a ball grid array (BGA) package 302. The BGA package 302 is so named due to the array of solder balls 350, or spheres of conductive material (e.g., tin-lead), which may be located on the bottom of the package substrate 320. A plurality of thin, metal bond wires 330 serve to electrically connect the semiconductor die 310 to conductive layers 322 within the package substrate 320. The bond wires 330, conductive layers 322 and solder balls 350 form a pathway of electrical communication between the die 310 and the PCB. A semiconductor die 310 is shown attached to a package substrate 320 with a low-CTE die attach material 318.

A low-CTE die attach material 318 preferably comprises an epoxy with a negative-CTE filler, such as zirconium tungstate (ZrW₂O₈), halfnium tungstate (HfW₂O₈), or a solid solution of zirconium and halfnium tungstate (Z_{0.5}Hf_{0.5}W₂O₈). The low-CTE die attach material 318 may further comprise a conventional conductive filler (e.g., silver flakes) or a non-conductive filler (e.g., silica) to improve flow properties of the die attach material and reduce cost. A filler material may alter the viscosity, expansion, or thermal properties of the packaging material in which it is introduced. Filler materials have a lower CTE than the packaging material in which they are mixed. This is generally done to more closely approximate the CTE of a silicon die, which may be about 3 ppm/C.

The die attach material 318 may be dispensed onto a chip carrier, such as a package substrate 320 or metal leadframe (not shown). The die 310, singulated from a wafer (not shown), is positioned onto the die attach material 318 by a pick-and-place operation, compressing the die attach material to form a mechanical bond. The mounted units, i.e., dies mounted on top of a package substrate or leadframe, may then go through a post-mount cure process in an oven for a few minutes up to 1 to 2 hours. Some die attach materials may be “fast cured” at the die-mounting stage. In such cases, the post-mount cure process may be eliminated.

The package substrate 320 may be a laminate structure comprising alternating layers of conductive material 322 and insulating material 324. The die 310 may be electrically interconnected to the package substrate 320 by a plurality of bond wires 330. The die 310 and bond wires 330 may be encapsulated by a low-CTE, solid encapsulant 340, e.g., an epoxy mold or glob-top compound, protecting the bond wires from physical damage and/or environmental effects. A low-CTE encapsulant 340 in accordance with the embodiments shown preferably comprises an epoxy with a negative-CTE filler, such as zirconium tungstate, halfnium tungstate, a solution of zirconium and halfnium tungstate or another suitable negative-CTE material. A low-CTE encapsulant 340 may further comprise a conventional non-conductive filler, e.g. silica, to improve flow properties and reduce cost.

Low-CTE mold compound is a type of low-CTE encapsulant 340 that may comprise an epoxy base (e.g., epoxy o-cresol novolac, biphenyl or multifunctional resin) and a negative-CTE filler. Optionally, a non-conductive filler (e.g., silica) may be included to improve flow properties and reduce cost. The encapsulation of a die 310 by mold compound may be performed by preheating mold compound pellets, melting the pellets, and transferring the mold compound through runners (not shown) into cavities by applying a ramping pressure at a molding temperature. At the end of pressure ramping, the mold compound may fill the cavities, encapsulating dies 310 disposed in the cavities. This process is called transfer molding. The mold compound may then be cured at the final ramping pressure and at the molding temperature for a few seconds up to 1 or 2 minutes. Molded dies may be removed from the cavities and cured again in an oven at a post-mold cure temperature for a few hours. Some mold compounds (i.e., “snap cure” compounds) are designed to be cured in a short time. In that case, post-mold cure may be shortened or eliminated.

A low-CTE glob-top material is another type of encapsulant 340, which may comprise epoxy base with a negative-CTE filler. Optionally, a non-conductive (e.g., silica) filler, typically at a much smaller weight percent than mold compound, may be included, as well as other minor additives. The encapsulation process using a glob-top material may be performed by dispensing glob-top material directly onto a die 310, which has already been mounted to a package substrate 320 or a PCB, followed by a cure process. The glob-top compound is so named due to the fact that is not molded in a cavity to take a specific shape, but may be dispensed onto a die, possibly forming a somewhat round-edged “glob.” It will be understood that, while a general encapsulant 340 is shown in FIG. 1, it may physically represent either a mold compound or a glob-top encapsulant, as the two may be used interchangeably in package assembly.

While a low-CTE die attach material 318 and a low-CTE encapsulant 340 may both comprise resin- or epoxy-based materials containing a negative-CTE material, it will be understood that they may be distinguished by usage and electrical properties. In addition to a negative-CTE material, a low-CTE die attach material 318 may also comprise either a conductive filler (e.g., silver flakes) or a non-conductive filler (e.g., silica). As such, a low-CTE die attach material 318 may be electrically conductive. A low-CTE encapsulant 340 would preferably be designed as electrically non-conductive, as it may contact electrically active surfaces of the die 310 and may flow around conductive bond wires 330. Further, a low-CTE encapsulant 340 may be designed with such a viscosity as to allow either mold injection (e.g., for a mold compound encapsulant) or needle-dispensing (e.g., for a glob-top encapsulant). This may be accomplished by varying the epoxy base or the respective contents of the negative-CTE filler and conventional filler (if used).

Referring now to FIG. 4, a low-CTE packaged semiconductor device 400 is shown as comprising a die 410 packaged in a land grid array (LGA) package 402. The LGA package 402 is so named because the lower surface 428 of the substrate 420 may be populated with a grid array of electrical contact lands 432. The die 410 is oriented with its active (or “top”) surface 412 facing down towards the package substrate 420, in an upside-down, or “flip-chip,” configuration. Solder bumps 418 arranged on the active surface 412 of the die 410 may be attached to the upper surface 426 of the substrate 420 by an oven reflow process.

After the die 410 is attached to the substrate 420, an underfill material 416 may be injected under the die and around solder bumps 418 to improve the reliability of the connections between the solder bumps and the substrate. A low-CTE lid attach material 442, such as an epoxy or silicone, may be applied to the back surface 418 of the die 410 as well as around the perimeter of the upper surface 426 of substrate 420. A rigid lid 440 in the shape of an open-ended box is then positioned open-side-down over the substrate 420, such that the inside surface 444 of the lid contacts the low-CTE lid attach 442 on the inactive die surface 414. The perimeter edges 434 of the lid 440 contact the low-CTE lid attach material 442 on the upper surface 426 of the substrate 420, thereby forming a cavity 460 around the die. It should be noted that the package 402 comprises the substrate 420 and lid 440, whereas the packaged semiconductor device 400 comprises both the package 402 and all its constituent components, as well as the die(s) 410 mounted within the package.

The low-CTE lid attach material 442 preferably comprises an epoxy with a negative-CTE filler, such as zirconium tungstate, halfnium tungstate, a solution of zirconium and halfnium tungstate or another suitable negative-CTE material. The low-CTE lid attach material 442 may also comprise a conductive filler (e.g., silver flakes) or a non-conductive filler (e.g., silica) as well as other minor additives, depending on the requirements of the packaged semiconductor device 400. The low-CTE lid attach material 442 may be dispensed onto the backside of a flip-chip that has been mounted to a substrate, as shown in FIG. 4, by a solder-reflow process. A rigid lid 440 may be placed on the backside of the die by compressing the low-CTE lid attach material 442 into a desired bond thickness. A post-mount cure process may be needed after the lid-attach process to cure the low-CTE lid attach material 442.

The underfill material 416 may be distinguished from a low-CTE die attach material in that the low-CTE die attach material may be thermally and electrically conductive, and may be used to attach the inactive surface of a face-up, wirebonded die to a substrate. Conversely, the underfill material 416 may not be electrically conductive and may be used to reinforce solder bump joints, which may connect the active surface of a flip-chip die to a substrate. The low-CTE lid attach material 442 may be distinguished from a die attach material in that the low-CTE lid attach material may be applied to the inactive surface 414 of a flip-chip die 410. A die attach material may be applied to the inactive surface of a die designed for wirebonding, such as that shown in FIG. 1.

Incorporating a negative-CTE material as a distinct filler or as a constituent of a composite material in a packaging material as discussed may lessen the CTE mismatches and associated stresses common in packaged semiconductor devices. As physical damage may result from excessive material stresses seen during temperature variances occurring during testing and operation, reducing CTE mismatches is critical for the prolonged operation of a packaged semiconductor device. Increasing the amount of negative-CTE material introduced into a die attach material or an encapsulant may allow the respective packaging material to more closely approximate the CTE of an adjacent die (e.g., 3 ppm/C for silicon). Further, varying the amount of negative-CTE material introduced into a lid attach material may allow the CTE of the lid attach material to more closely approach that of the adjacent lid and/or die.

Certain embodiments of a packaged semiconductor device have been shown herein as comprising specific low-CTE packaging materials. However, it will be understood that a low-CTE packaged semiconductor device may comprise any combination of the low-CTE packaging materials, depending on the needs and configuration of the specific device. The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

1. A packaging material for assembling a semiconductor die, the packaging material comprising a negative-CTE material, wherein the packaging material is a material selected from a group consisting of mold compound, glob-top material, die attach material, and lid attach material.

2. The packaging material of claim 1, wherein the negative-CTE material comprises a tungstate material.

3. The packaging material of claim 2, wherein the tungstate material comprises a material selected from a group consisting of zirconium tungstate, halfnium tungstate, and a solution of zirconium and halfnium tungstate.

4. A method comprising:
dispensing a die attach material onto a chip carrier, wherein the die attach material comprises a negative-CTE material; and
attaching a semiconductor die to the die attach material.

5. The method of claim 4, wherein dispensing the die attach material onto the chip carrier further comprises dispensing the die attach material onto a structure selected from a group consisting of a package substrate and a leadframe.

6. The method of claim 4, wherein dispensing a die attach material comprising a negative-CTE material further comprises dispensing a die attach material comprising a tungstate material.

7. The method of claim 6, wherein dispensing a die attach material comprising a negative-CTE material further comprises dispensing a die attach material comprising a material selected from a group consisting of zirconium tungstate, halfnium tungstate and a solution of zirconium and halfnium tungstate.

8. A method comprising:
attaching a semiconductor die to a chip carrier; and
encapsulating the semiconductor die with an encapsulant comprising a negative-CTE material.

9. The method of claim 8, wherein attaching the semiconductor die to a chip carrier further comprises attaching the semiconductor die to a structure selected from a group consisting of a package substrate and a leadframe.

10. The method of claim 8, wherein encapsulating the semiconductor die with an encapsulant comprising a negative-CTE material further comprises encapsulating the semiconductor die with an encapsulant comprising a tungstate material.

11. The method of claim 10, wherein encapsulating the semiconductor die with an encapsulant comprising a tungstate material further comprises encapsulating the semiconductor die with a material selected from a group consisting of zirconium tungstate, halfnium tungstate and a solution of zirconium and halfnium tungstate.

12. The method of claim 11, wherein encapsulating the semiconductor die with an encapsulant comprising a negative-CTE material further comprises encapsulating the semiconductor die with a material selected from a group consisting of a mold compound and a glob-top material.

13. A method comprising:
dispensing a lid attach material onto a package substrate and an inactive surface of a semiconductor die, wherein the lid attach material comprises a negative-CTE material; and
adhering a package lid to the lid attach material.

14. The method of claim 13, wherein dispensing the lid attach material comprising a negative-CTE material further comprises dispensing a lid attach material comprising a tungstate material.

15. The method of claim 14, wherein dispensing the lid attach material comprising a tungstate material further comprises dispensing a lid attach material comprising a material selected from a group consisting of zirconium tungstate, halfnium tungstate, and a solution of zirconium and halfnium tungstate.

16. A semiconductor die assembled into a packaged semiconductor device by a method comprising:
dispensing a die attach material onto a chip carrier, wherein the die attach material comprises a negative-CTE material; and
attaching a semiconductor die to the die attach material.

17. The semiconductor die of claim 16, wherein dispensing the die attach material onto the chip carrier further comprises dispensing the die attach material onto a structure selected from a group consisting of a package substrate and a leadframe.

18. The semiconductor die of claim 17, wherein dispensing a die attach material comprising a negative-CTE material further comprises dispensing a die attach material comprising a tungstate material.

19. The semiconductor die of claim 16, wherein the method further comprises encapsulating the semiconductor die with an encapsulant comprising a negative-CTE material.

20. The semiconductor die of claim 19, wherein encapsulating the semiconductor die with an encapsulant comprising a negative-CTE material further comprises encapsulating the semiconductor die with an encapsulant comprising a tungstate material.

21. The semiconductor die of claim 19, wherein encapsulating the semiconductor die with an encapsulant further comprises encapsulating the semiconductor die with a material selected from a group consisting of a mold compound and a glob-top material.

22. A semiconductor die assembled into a packaged semiconductor device by a method comprising:
dispensing a lid attach material comprising a negative-CTE material over the inactive surface of a semiconductor die and around at least a portion of a perimeter of the upper surface of a package substrate; and
adhering a package lid to the lid attach material.

23. The method of claim 22, wherein dispensing the lid attach material comprising a negative-CTE material further comprises dispensing a lid attach material comprising a tungstate material.

24. The method of claim 23, wherein dispensing the lid attach material comprising a tungstate material further comprises dispensing a lid attach material comprising a material selected from a group consisting of zirconium tungstate, halfnium tungstate, and a solution of zirconium and halfnium tungstate.
